(19) United States
(12) Patent Application Publication
(10) Pub. No.: US 2008/0081270 A1
(43) Pub. Date: Apr. 3, 2008

(54) PHOTO-CURABLE COMPOSITION, COLOR FILTER AND METHOD FOR PRODUCING THE SAME, AND SOLID STATE IMAGER

(75) Inventor: Tatsuya TANAKA, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/864,777

(22) Filed: Sep. 28, 2007

(30) Foreign Application Priority Data
Sep. 28, 2006 (JP) 2006-264606
Mar. 27, 2007 (JP) 2007-081713

(51) Int. Cl. G03F 1/00; C08F 22/00

(52) U.S. Cl. 430/7; 522/65

(57) ABSTRACT

The invention provides a photo-curable composition having at least: (A) a binder polymer; (B) a multifunctional photo-curable compound having at least one selected from the group consisting of acidic functional groups and alkyleneoxy chains; (C) an oxime photopolymerization initiator; and (D) a pigment. The acidic functional group is preferably a carboxyl group. The (B) multifunctional photo-curable compound preferably has at least one selected from the group consisting of a pentaerythritol compound and a dipentaerythritol compound. The invention further provides a color filter formed using the photo-curable composition, and a solid state imager having at least the color filter.

### BACKGROUND OF THE INVENTION

1. Field of Invention

The present invention relates to a photo-curable composition, a color filter a method for producing the same, and o a solid state imager using the same.

2. Description of the Related Art

In the late 1990s, color filters for image sensors had a pixel size of around 5 μm in response to demands for improved resolution of solid state imagers, such as CCD. In recent years, pixel size has been further decreased to 2.5 μm or less.

As the size of pixels becomes smaller, technical problems associated with the shape of pixels formed by photolithography have been revealed.

That is, in production of color filters using a photoresist method, a pixel pattern is exposed onto a photoresist coating film that is formed on a substrate by coating and colored with a dispersing pigment through a photomask and then alkaline development is carried out to form a pixel. However, as the size of pixel becomes smaller, the contact surface between an alkaline developer and non-exposed parts becomes smaller and further the generation of residue due to the poor solubility is increased and the pattern shape is often tapered. The sensitivity of pixels adjacent to each other is lowered due to the generation of residue. The colors of pixels adjacent to each other are mixed and interstices between pixels are formed due to high degree of tapering. Therefore, in the reproduced picture image of a solid state imager, there is a high degree of both image noise and surface roughness. Thus, problems arise in which quality of image is easily impaired.

In addition, there has been recently a pressing need for thinner color filters with higher coloring density in order to improve image quality by high light-harvesting and high color separation. When a large amount of coloring material is added to a color filter to obtain a high coloring density, the alkaline development property is lowered.

Conventionally, acrylates of dipentaerythritol such as dipentaerythritolhexaacrylate or dipentaerythritolpentaacrylate have been used as a photopolymerized compound of a colored photo-curable composition. However, these compounds have low solubility in an aqueous alkaline developer and when a refined pixel pattern, particularly with a size of 2.5 μm or less, is formed, the generation of residue is remarkably increased due to the poor solubility of non-exposed parts.

Techniques using multifunctional photo-curable compounds having a carboxyl group for improvement of alkaline development (such as Japanese patent Application Laid-Open (JP-A) Nos. 10-332929, 2004-287230, and 2005-148717) and radiation sensitive colored compositions having a (meth)acrylate compound having a structure of alkylene oxide such as ethyleneoxide and propylene oxide (such as JP-A No. 10-62986) are known.

On the other hand, a compound in which an acid group is introduced into dipentaerythritol or pentaerythritol is known as a monomer mixed into a solder resist (such as JP-A Nos. 8-123027 or 8-123028). Further, a solder resist ink composition prepared by using a material in which the material is a tetra-functional acrylate monomer and an acryloyl group is connected by a ring-opening structure, e.g. ethyleneoxide and propylene oxide (such as JP-A No. 2-38471), or a photosensitive resin composition similar to the solder resist ink composition are known (such as JP-A No. 64-25147). In addition, a coating material composition that is a photopolymerization composition having a multifunctional acrylate such as polypentaerythritol polyacrylate is also known (such as JP-A No. 1-126345).

However, the multifunctional photo-curable compounds having a carboxyl group or a radiation sensitive colored composition having a (meth)acrylate compound having a structure of alkylene oxide such as ethyleneoxide and propylene oxide are mainly used for a liquid crystal display. The sensitivity is not sufficient to precisely reproduce the shape of a pattern with a refined size of 2.5 μm or less as used in an image sensor. Therefore, there have been many cases in which techniques using these compositions have tended to result in overall failure of the pattern. Since high energy light irradiation is required to correct the failure, exposure time becomes longer and the manufacturing yield is significantly reduced.

Further, the pigment concentration of the above-mentioned solder resist is lower compared to resists for color filters and the respective resists completely differ in terms of composition mixture, use, and performance requirements. Further, they completely differ in terms of the effect of a monomer having an acid group, so the technique of the solder resist cannot be directly applied to resists for color filter.

It should be remarked that JP-A No. 2-38471, which concerns a solder resist ink composition as described above, does not describe a penta-functional or hexa-functional acrylate monomer used for a color filter. Further, JP-A No. 64-25147, which concerns a photosensitive resin composition as described above, does not describe use of the photosensitive resin composition in a color filter. Furthermore, JP-A No. 1-126345, which concerns a coating material composition as described above, does not have a description of use of the coating material composition in a color filter or a description of introduction of ring-opening structures of ethyleneoxide and propylene oxide into the acrylate.

Therefore, it is deemed difficult to form a pixel pattern with refined dimensions of 2.5 μm or less and an approximately rectangular cross-sectional shape with low light exposure and to suppress the generation of residue between pixels using conventional techniques.

### SUMMARY OF THE INVENTION

The present invention was achieved in view of the above circumstances and provides a photo-curable composition which can form a pixel pattern with refined dimensions (for example, a line width of 2.5 μm or less) with a low amount of light exposure and suppress the generation of development residue between pixels, and further provides a color filter and a method for producing the same.

The present inventors found that a refined and rectangular pixel pattern with a line width of 2.5 μm or less can be formed and the generation of residue between pixels can be suppressed by using a photo-curable composition which includes a multifunctional photo-curable compound having one or more acidic functional groups and/or one or more alkyleneoxy chains and further includes an oxime photopolymerization initiator even when the amount of a photopolymerization component is decreased in order to add a large amount of a pigment to a photo-curable composition as a coloring agent.

Namely, the invention provides a photo-curable composition comprising: (A) a binder polymer; (B) a multifunctional photo-curable compound having at least one selected from the group consisting of acidic functional groups and alkyleneoxy chains; (C) an oxime photopolymerization initiator; and (D) a pigment.

In one aspect of the photo-curable composition, the (B) multifunctional photo-curable compound comprises an acidic functional group that is a carboxyl group.

In another aspect of the photo-curable composition, the (B) multifunctional photo-curable compound comprises three or more photo-curable functional groups.

In another aspect of the photo-curable composition, the (B) multifunctional photo-curable compound comprises at least one selected from the group consisting of a pentaerythritol compound and a dipentaerythritol compound.

In another aspect of the photo-curable composition, the (B) multifunctional photo-curable compound comprises at least one selected from the group consisting of a compound represented by Formula (i) or (ii).

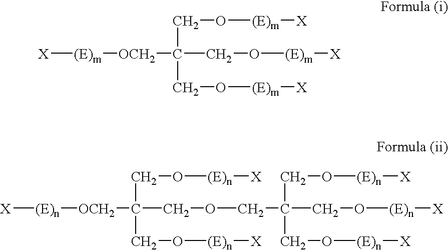

In Formulae (i) and (ii), each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group.

In Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group.

In Formula (ii), the sum of the number of acryloyl groups and the number of methacryloyl groups is 5 or 6; each n independently represents an integer from 0 to 10; and the sum of n is an integer from 0 to 60, provided that if the sum of n is 0, any one X is a carboxyl group.

The invention further provides a method for producing a color filter comprising: applying the photo-curable composition onto a substrate; exposing the applied composition through a mask; and developing the exposed composition so as to form a pattern

The invention further provides a color filter formed using the photo-curable composition.

The invention furthermore provides a solid state imager comprising the color filter.

### BRIEF DESCRIPTION OF THE DRAWINGS

FIG. 1 is a mask pattern of a photomask used for a pattern exposure in the present Examples.

FIG. 2 is a view showing typical aspects of each of the classified types of the development residue generated in the Examples.

### DETAILED DESCRIPTION OF THE INVENTION

The photo-curable composition of the invention is configured by having at least (A) a binder polymer; (B) a multifunctional photo-curable compound having at least one selected from the group consisting of acidic functional groups and alkyleneoxy chains; (C) an oxime photopolymerization initiator; and (D) a pigment. The photo-curable compound of the invention may further contain a solvent and/or any other ingredient(s).

The configuration of the photo-curable composition of the invention allows formation of a pixel pattern with refined dimensions (e.g. 2.5 μm or less) and a cross-sectional shape which is substantially rectangle with a low light exposure, and suppression of the generation of residue between pixels. Hereinafter, each component will be described in detail.

(A) Binder Polymer

The photo-curable composition of the invention contains at least one binder polymer.

While the binder polymer is not particularly limited, it is preferable to use one that is a linear organic high molecular polymer, is soluble in an organic solvent and can be developed with a weak alkaline solution. Examples of the linear organic high molecular polymer include a polymer having a carboxylic acid on a side chain such as a methacrylic acid copolymer, an acrylic acid copolymer, an itaconic acid copolymer, a crotonic acid copolymer, a maleic acid copolymer, or a partially esterificated maleic acid copolymer, as described in JP-A No. 59-44615; JP-B Nos. 54-34327, 58-12577, and 54-25957; and JP-A Nos. 59-53836 and 59-71048. Examples of the linear organic high molecular polymer further include an acidic cellulose compound having a carboxylic acid on the side chain. Examples of the linear organic high molecular polymer further include a substance formed by adding an acid anhydride to a polymer having a hydroxy group. Among these polymers, a benzyl(meth)acrylate/(meth)acrylic acid copolymer and a multi-copolymer of benzyl(meth)acrylate/(meth)acrylic acid/another monomer are preferable. In addition, 2-hydroxyethyl methacrylate, polyvinyl pyrrolidone, polyethylene oxide, polyvinyl alcohol, and the like are useful as water-soluble polymers.

Furthermore, examples of the water-soluble polymer include 2-hydroxypropyl(meth)acrylate/polystyrenemacromonomer/benzylmethacrylate/methacrylic acid copolymer, 2-hydroxy-3 phenoxypropylacrylate/polymethylmethacrylatemacromonomer/benzylmethacrylate/methacrylic acid copolymer, 2-hydroxyethylmethacrylate/polystyrenemacromonomer/methylmethacrylate/methacrylic acid copolymer, and 2-hydroxyethylmethacrylate/polystyrenemacromonomer/benzylmethacrylate/methacrylic acid copolymer which are described in JP-A No. 7-140654.

The content of the binder polymer in the photo-curable composition of the invention is preferably in a range of 5 to 90% by mass, and more preferably in a range of 10 to 60% by mass relative to the total mass of the compositions.

The content of the binder polymer in the photo-curable composition of the invention is preferably in a range of 20 to 60% by mass, and more preferably in a range of 10 to 40% by mass relative to total solid content.

The term “total solid content” used herein means all components except for solvents.

If the content is within the range described above, the content of a pigment in the photo-curable composition of the invention can be increased without impairing effects achieved by the invention and the pattern formed therewith can be further made thinner and refined.

(B) Multifunctional Photo-Curable Compound Having One or More Acidic Functional Groups and/or One or More Alkyleneoxy Chains

The photo-curable composition of the invention contains (B) at least one multifunctional photo-curable compound having one or more acidic functional groups and/or one or more alkyleneoxy chains as an essential ingredient.

The term “multifunctional photo-curable compound” used herein means a photo-curable compound having two or more photo-curable functional groups. Hereinafter, the term “(B) multifunctional photo-curable compound having one or more acidic functional groups and/or one or more alkyleneoxy chains” may be referred to as the “particular photo-curable compound”.

There are three forms of the particular photo-curable compound in the invention, namely: (B-1) a multifunctional photo-curable compound containing at least one or more acidic functional groups while having no alkyleneoxy chain (hereinafter referred to as “AO chain”); (B-2) a multifunctional photo-curable compound containing at least one or more AO chains while having no acidic functional group; and (B-3) a multifunctional photo-curable compound containing at least one or more acidic functional groups and one or more AO chains.

When two or more of the particular photo-curable compounds are contained in the photo-curable composition of the invention, the two or more specified photo-curable compounds may be selected either from the group consisting of the particular photo-curable compounds belonging to one of (B-1) to (B-3) or from the group consisting of the particular photo-curable compounds of two or three of (B-1) to (B-3).

The particular photo-curable compound in the invention preferably has relatively small molecular size. It is particularly preferable to use a compound in which the polystyrene conversion weight average molecular weight is less than 3,000.

When the particular photo-curable compound having an acidic functional group is mixed with a photo-curable composition, the crosslinking density of a crosslinking structure formed from the photo-curable composition is increased by the photo-curable functional group of the compound, and the alkali solubility of an unexposed portion of the photo-curable composition having the compound is increased by the acidic functional group of the compound. Since the crosslinking density and alkali solubility of the photo-curable composition are thus increased by adding the particular photo-curable compound having an acidic functional group thereto, an excellent curing property and alkaline development property can be obtained even if the amounts of components having no curing reactivity and no alkali solubility, such as a coloring agent or a photopolymerization initiator, are increased.

Any acidic functional groups may be contained in the particular photo-curable compound as long as the photo-curable composition including the acidic functional group(s) can be subjected to alkaline development. Examples of the acidic functional group include a carboxyl group, a sulfonic acid group, and a phosphate group. From the viewpoint of suitability to alkaline development and handling of the resin composition, a carboxyl group is preferable.

When the particular photo-curable compound having an alkyleneoxy chain is mixed with the photo-curable composition, the crosslinking density is increased by the photo-curable functional group of the compound, and a hydrophilicity of the photo-curable composition having the compound is increased by the alkyleneoxy chain of the compound, thereby increasing a solubility of unexposed portion of the photo-curable composition having the compound in an aqueous alkaline developer. Since the crosslinking density and alkali solubility of the photo-curable composition are thus increased by adding the particular photo-curable compound having an alkyleneoxy chain thereto, an excellent curing property and alkaline development property can be obtained even if the amounts of components having no curing reactivity and no alkali solubility, such as a coloring agent or a photopolymerization initiator, are increased.

While the kind of reaction of the photo-curable functional group of the particular photo-curable compound is not limited and it may be any one of a photo-radical reaction, a photo-cationic reaction, and a photo-anionic reaction, the photo-curable functional group is preferably a photo radical reactive group obtained by photo-radical polymerization or photo-radical dimerization, and is particularly preferably a group having an ethylene unsaturated bond such as a (meth)acryloyl group. Preferable examples thereof include an acryloyl group and a methacryloyl group, and more preferable examples thereof include an acryloyl group.

The larger the number of photo-curable functional groups of the particular photo-curable compound, the more preferable in terms of increasing the crosslinking density.

The number of photo-curable functional groups in the particular photo-curable compound having the AO chain is preferably three or more, is more preferably three to thirty, and is particularly preferably three to fifteen from the viewpoint of the crosslinking density.

The number of photo-curable functional groups in the particular photo-curable compound having an acidic functional group is preferably three or more from the viewpoint of the crosslinking density.

The particular photo-curable compound preferably includes a pentaerythritol compound and/or a dipentaerythritol compound in view of further efficiently obtaining effects of the invention.

Examples of the particular photo-curable compound having an acidic functional group include: (1) a compound in which a carboxyl group is introduced by denaturing, with a dibasic acid anhydride, a monomer or oligomer having a hydroxyl group and three or more photo-curable functional groups; and (2) a compound in which a sulfonic acid group is introduced by denaturing, with concentrated sulfuric acid or fuming sulfuric acid, an aromatic compound having three or more photo-curable functional groups. Further, an oligomer having a monomer that is the particular photo-curable compound itself as a repeating unit may be used as the particular photo-curable compound.

Preferable examples of the particular photo-curable compound used in the invention include at least one selected from the group consisting of a compound represented by Formulae (1) or (2). In Formulae (1) and (2), when T or G is an alkyleneoxy chain, R, X, and W are bound to the terminal carbon atom of T or G.

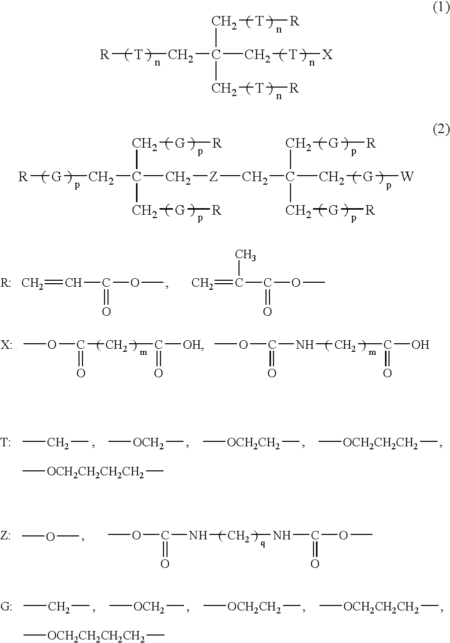

In Formula (1), n represents an integer of 0 to 14, and m represents an integer of 1 to 8. In Formula (2), the scope of W is the same as that of R or X in Formula (1) and three or more Ws of six Ws have the same scope as that of R. p represents an integer of 0 to 14, and q represents an integer of 1 to 8. A plurality of Rs, Xs, Ts, and Gs present in the molecule may be the same or different, respectively.

Among the compounds represented by Formulae (1) or (2), a pentaerythritol compound and a dipentaerythritol compound are more preferable.

Specific examples of the particular photo-curable compound represented by Formulae (1) or (2) include compounds represented by any one of the following formulae (3) to (14) (hereinafter, also referred to as exemplified compounds (3) to (14)). Among them, exemplified compounds (3), (4), (5), (7), and (9) are preferable.

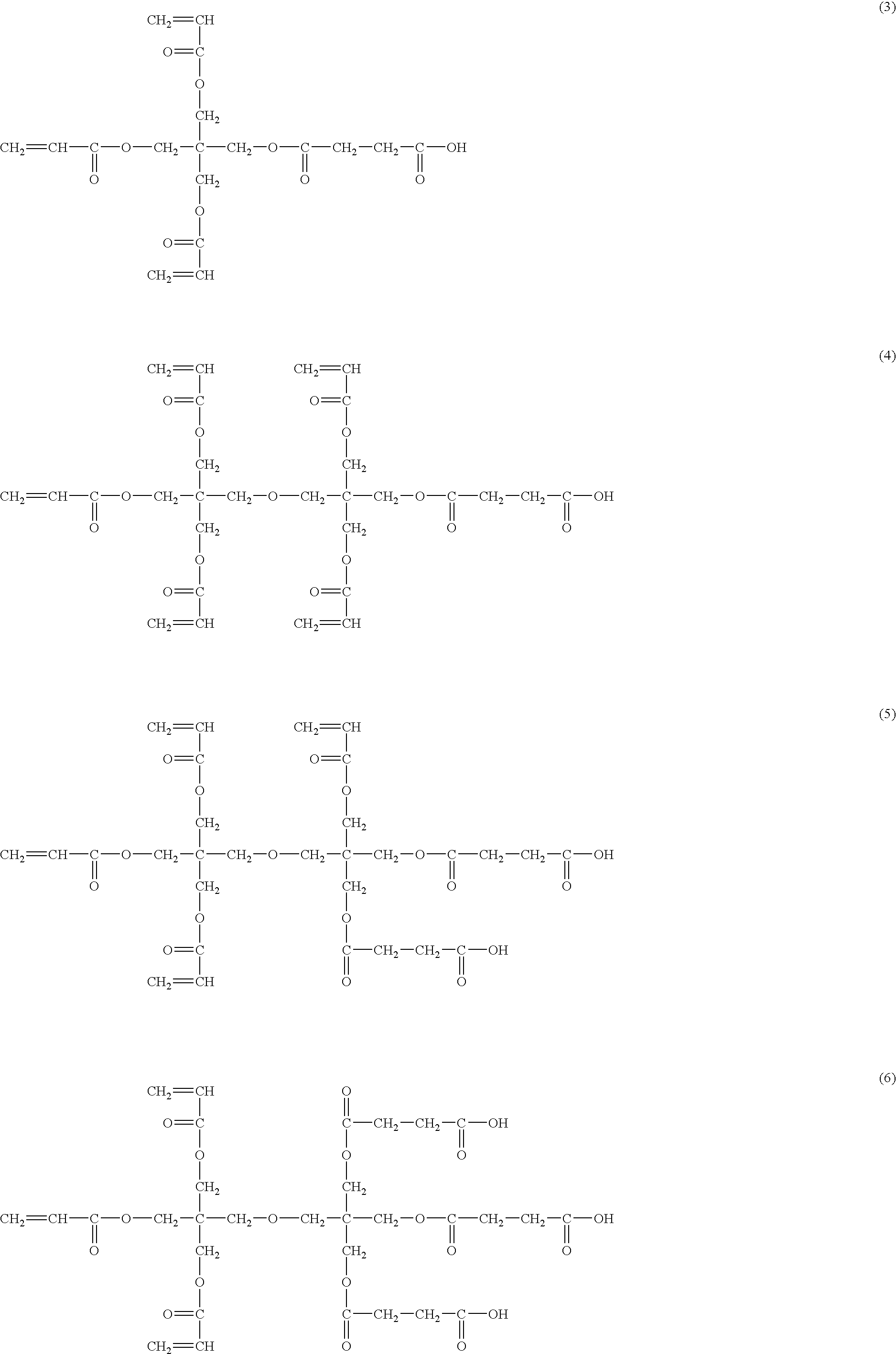

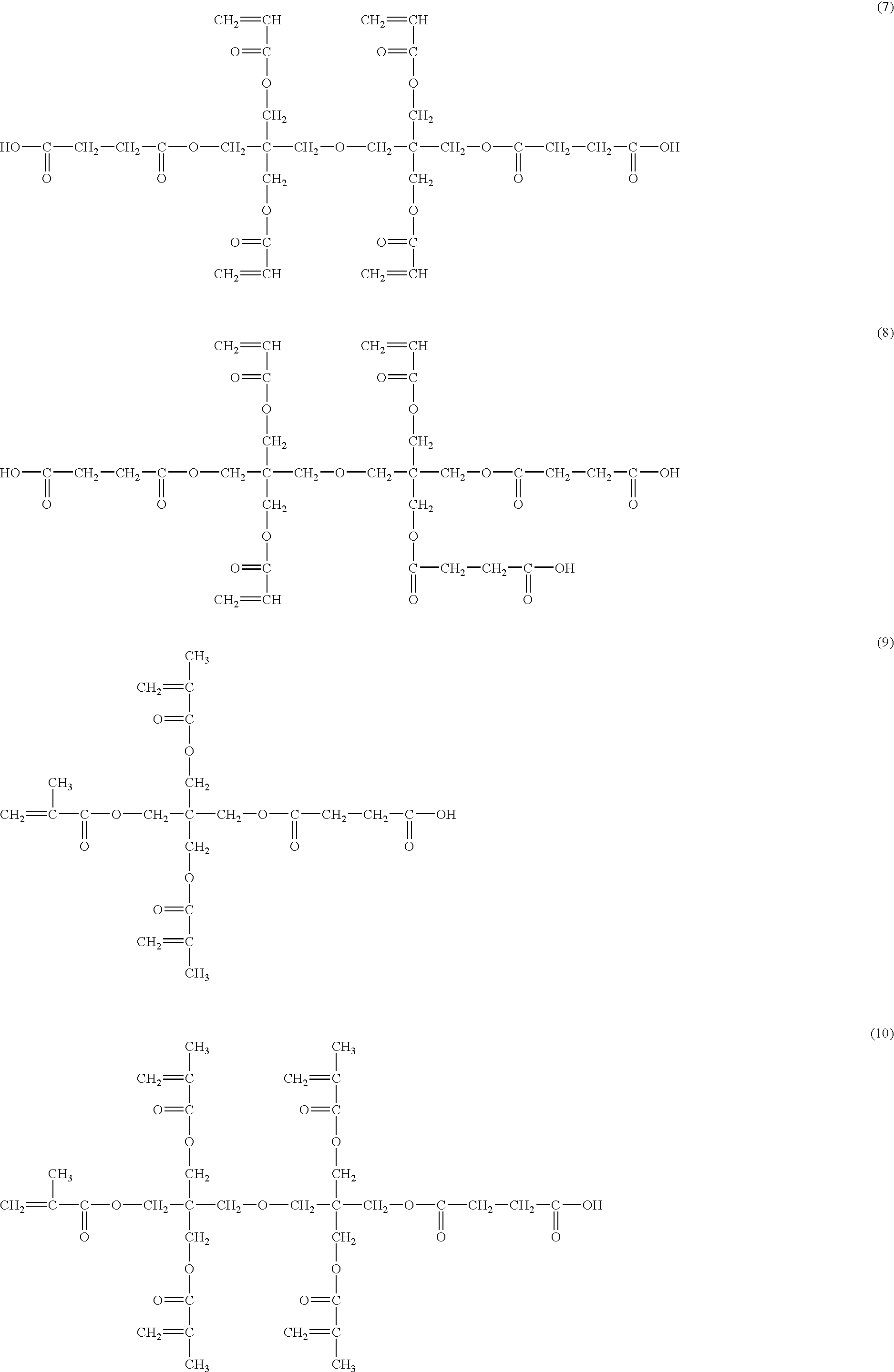

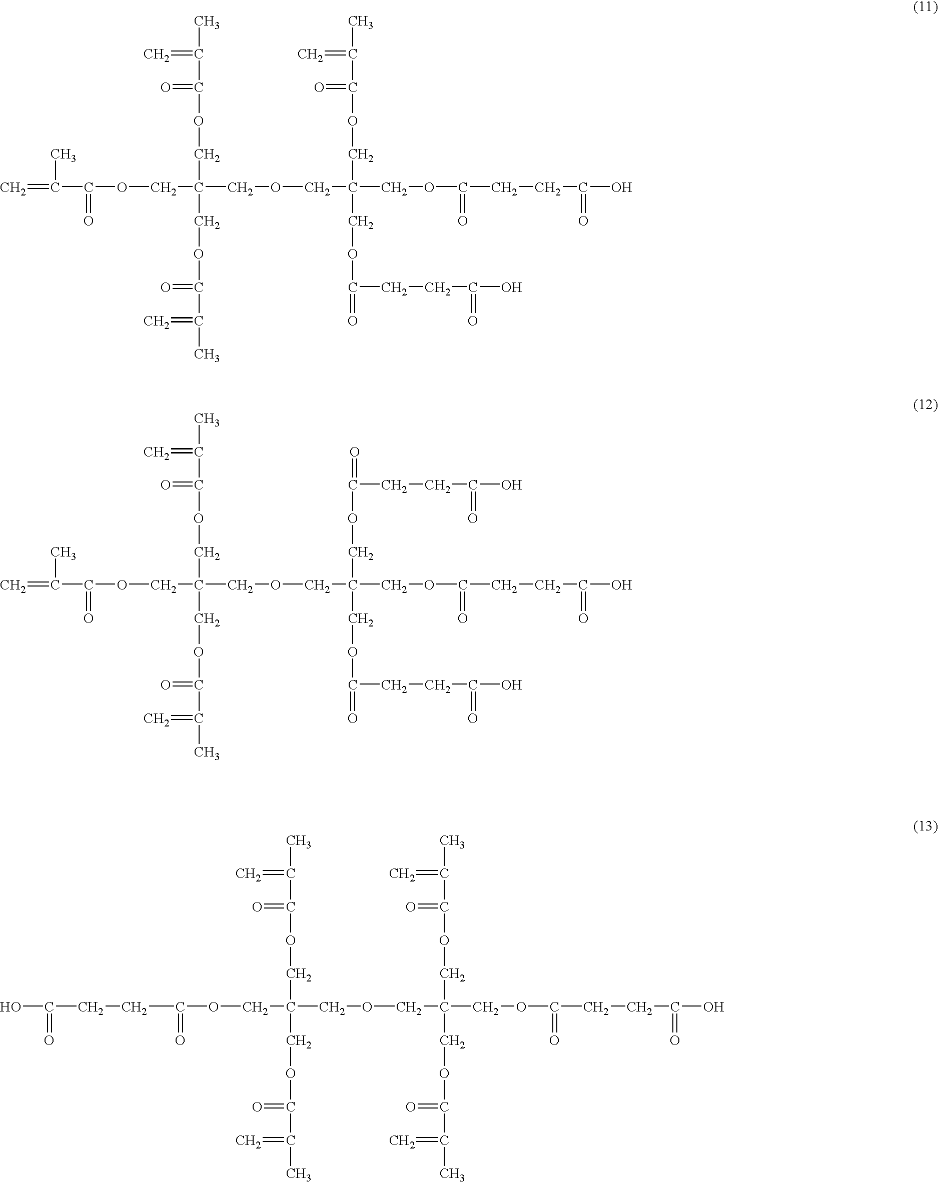

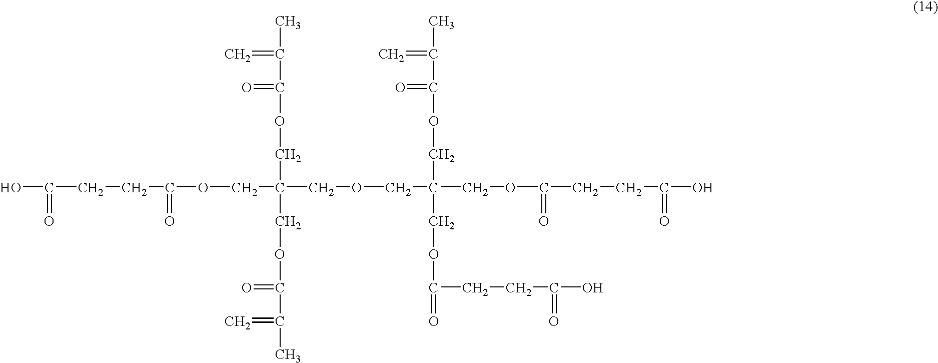

Commercially-available examples of the particular photo-curable compound represented by Formula (1) or (2) include TO-756, that is a tri-functional acrylate containing carboxyl groups, and TO-1382, that is a penta-functional acrylate containing carboxyl groups (both trade names, manufactured by TOAGOSEI CO., LTD.)

Preferable examples of the particular photo-curable compound used in the invention further include at least one selected from the group consisting of a compound represented by Formulae (i) or (ii).

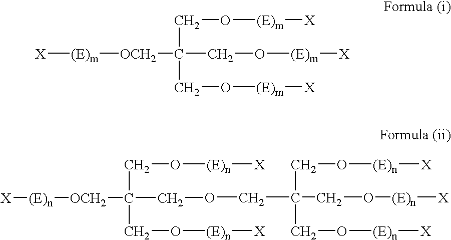

In Formulae (i) and (ii), each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group.

In Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group.

In Formula (ii), the sum of the number of acryloyl groups and the number of methacryloyl groups is 5 or 6; each n independently represents an integer from 0 to 10; and the sum of n is an integer from 0 to 60, provided that if the sum of n is 0, any one X is a carboxyl group.

In Formula (i), m is preferably an integer from 0 to 6, and more preferably an integer from 0 to 4. The sum of each m is preferably an integer from 2 to 40, is more preferably an integer from 2 to 16, and is particularly preferably an integer from 4 to 8.

In Formula (ii), n is preferably an integer from 0 to 6, and more preferably an integer from 0 to 4. The sum of each n is preferably an integer from 3 to 60, is more preferably an integer from 3 to 24, and is particularly preferably an integer from 6 to 12.

In Formula (i) or (ii), —((CH₂)_{y}CH₂O)— or —((CH₂)_{y}CH(CH₃)O)— is preferably bound to X via the terminal at the oxygen atom side.

The compounds represented by Formula (i) or (ii) may be used alone or in combination. Particularly, in Formula (ii), all of six Xs are preferably acryloyl groups.

The total content of the compounds represented by Formula (i) or (ii) relative to the amount of the particular photo-curable compound is preferably 20% by mass or more, and more preferably 50% by mass or more.

The compound represented by Formula (i) or (ii) can be synthesized by a method including: binding a ring-opened skeleton of ethylene oxide or propylene oxide to pentaerythritol or dipentaerythritol by a ring-opening addition reaction; and introducing a (meth)acryloyl group to a terminal hydroxyl group of the ring-opened skeleton by, for example, reacting with (meth)acryloyl chloride. Each process is conventionally well known and the compound represented by Formulae (i) or (ii) can be easily synthesized by a person skilled in the art.

Among the compounds represented by Formulae (i) or (ii), it is preferable that a pentaerythritol compound and/or a dipentaerythritol compound is/are used in the invention.

Specific examples of the compounds represented by Formulae (i) or (ii) include compounds represented by any one of the following formulae (a) to (f) (hereinafter, also referred to as exemplified compounds (a) to (f)). Among them, exemplified compounds (a), (b), (e), and (f) are preferable.

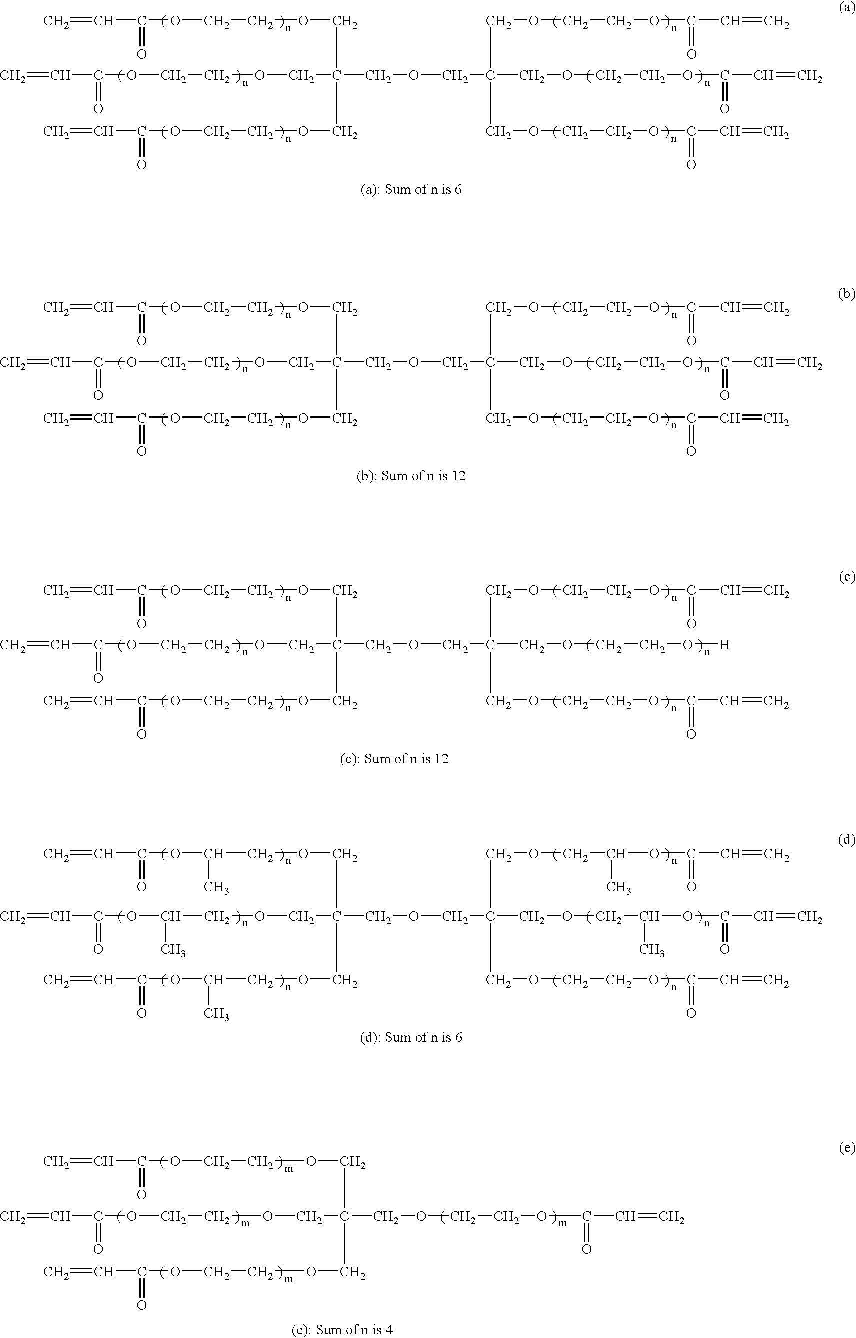

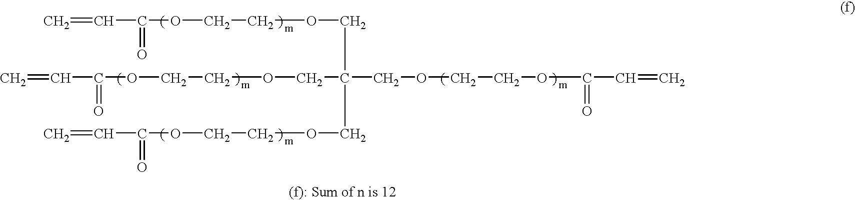

Commercially-available examples of the particular photo-curable compounds represented by Formulae (i) and (ii) include: SR-494 (trade name, manufactured by Sartomer Company, Inc.), which is a tetra-functional acrylate having four ethyleneoxy chains; KAYARAD DPCA-60 (trade name, manufactured by Nippon Kayaku Co., Ltd.), which is a hexa-functional acrylate having six pentyleneoxy chains; and KAYARAD TPA-330 (trade name, manufactured by Nippon Kayaku Co., Ltd.), which is a tri-functional acrylate having three isobutyleneoxy chains.

In addition, the photosensitive resin composition of the invention may further include a photo-curable compound having two or more photo-curable functional groups in addition to the particular photo-curable compound. Addition of the particular photo-curable compound allows for increasing both the crosslinking density and the alkali solubility. On the other hand, addition of the “photo-curable compound having two or more photo-curable functional groups” allows for increasing only the crosslinking density. Therefore, the crosslinking density and the alkali solubility can be controlled by using these compounds in combination.

Examples of the photo-curable compound having two or more photo-curable group include monofunctional acrylates or methacrylate such as polyethyleneglycol mono(meth)acrylate, polypropyleneglycol mono(meth)acrylate and phenoxyethyl (meth)acrylate; polyethyleneglycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate;

compounds adding ethyleneoxide or propyleneoxide followed by (meth)acrylating polyfunctional alcohols such as trimethylolpropane tri(acryloyloxypropyl)ether, tri(acryloyloxyethyl)isocyanulate, glycerin and trimethylol ethane; urethane acrylates described in JP-B Nos. 48-41708 and 50-6034 and JP-A No. 51-37193; polyester acrylates described in JP-A No. 48-64183 and JP-B Nos. 49-43191 and 52-30490; and polyfunctional acrylates and methacrylates such as epoxy acrylates such as epoxy acrylates as reaction products of epoxy resins and (meth)acrylic acid, and mixtures thereof. Other examples are those introduced as light-curable monomers and oligomers in Journal of Adhesion Society of Japan, Vol. 20, No. 7, p 300-308.

The content of the (B) particular photo-curable compound in the photo-curable composition of the invention is preferably 2 to 50% by mass, is more preferably 2 to 30% by mass, and is further preferably 2 to 15% by mass, relative to the total mass of the composition.

If the content is within the range described above, the content of a pigment in the photo-curable composition can be increased without impairing the effect of the invention and the pattern can be further thinned and refined.

(C) Oxime Photopolymerization Initiator

The photo-curable composition of the invention contains at least one oxime photopolymerization initiator in view of obtaining polymerization property.

Particularly preferable examples of the oxime photopolymerization initiator include 2-(O-benzoyloxome)-1-[4-(phenyltio)phenyl]-1,2-octanedione and 1-(O-acetyloxime)-1-[9-ethyl-6-(2-methylbenzoyl)-9H-carbazol-3-yl]ethanone. Commercially-available examples of these include CGI-124 and CGI-242 ((both trade names, manufactured by Ciba Specialty Chemicals, Inc.).

From the viewpoint of more effectively carrying out the polymerization and more effectively suppressing enlargement of images (pixels) in the pattern by reducing an excessive rate of polymerization, the content of the oxime photopolymerization initiator in the photo-curable composition of the invention is preferably 1.0 to 30.0% by mass, more preferably 2.0 to 25.0% by mass, and particularly preferably 5.0 to 20.0% by mass, relative to the total mass of the composition.

If the content is within the range described above, the content of a pigment in the composition of the invention can be increased without impairing the effect of the invention and the pattern can be further thinned and refined.

Other photopolymerization initiator may also be used together with the oxime photopolymerization initiator. The additional photopolymerization initiators are not particularly restricted so long as they are able to polymerize monomers having polymerizable groups, and are preferably selected in terms of characteristics, initiation efficiency, absorption wavelength, availability and cost.

Specific examples of the additional photopolymerization initiator include at least one active halogen compounds selected from halomethyl oxadiazole compounds and halomethyl-s-triazine compounds, 3-aryl substituted coumalin compounds, lophine dimers, benzophenone compounds, acetophenone compounds and modified compounds thereof, and cyclopentadiene-benzene-iron complex and salts thereof.

Examples of the halomethyl oxadiazole compounds include 2-halomethyl-5-vinyl-1,3,4-oxadiazole compounds described in JP-B No. 57-6096, 2-trichloromethyl-5-styryl-1,3,4-oxadiazole, 2-trichloromethyl-5-(p-cyanostyryl)-1,3-4-oxadiazole and 2-trichloromethyl-5-(p-methoxystyryl)-1,3-4-oxadiazole.

Examples of the halomethyl-s-triazine compound include vinyl-halomethyl-s-triazine compounds described in JP-A No. 59-1281, and 2-(naphtho-1-yl)-4,6-bis-halomethyl-s-triazine and 4-(p-aminophenyl)-2,6-dihalomethyl-s-triazine compounds described in JP-A No. 53-133428.

Other examples include 2,4-bis(trichloromethyl)-6-p-methoxystyryl-s-triazine, 2,6-bis(trichloromethyl)-4-(3,4, methylenedioxyphenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphto-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxyethyl)-naphtho-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine,

2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, 4-[p-N,N-di(ethoxycarbonylmethyl)aminophenyl]-2,6-di(trichloromethyl)-s-triazine, 4-[o-methyl-p-N,N-di(ethoxycarbonylmethyl)aminophenyl]-2,6-di(trichloromethyl)-s-triazine, 4-[p-N,N-di(chloroethyl)aminophenyl]-2,6-di(trichloromethyl)-s-triazine, 4-[o-methyl-p-N,N-di(chloroethyl)aminophenyl]-2,6-di(trichloromethyl)-s-triazine, 4-(p-N-chloroethylaminophenyl)-2,6-di(trichloromethyl)-s-triazine, 4-(p-N-ethoxycarbonylmethylaminophenyl)-2,6-di(trichloromethyl)-s-triazine, 4-[p-N,N-di(phenyl)aminophenyl]-2,6-di(trichloromethyl)-s-triazine, 4-(p-N-chloroethylcarbonylaminophenyl)-2,6-di(trichloromethyl)-s-triazine, 4-[p-N-(p-methoxyphenyl)carbonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonylmethyl)aminophenyl]-2,6-di(trichloromethyl)-s-triazine,

4-[o-bromo-p-N,N-di(ethoxycarbonylmethyl)aminophenyl]-2,6-di(trichloromethyl)-s-triazine, 4-[o-chloro-p-N,N-di(ethoxycarbonylmethyl)aminophenyl]-2,6-di(trichloromethyl)-s-triazine, 4-[o-fluoro-p-N,N-di(ethoxycarbonylmethyl)-aminophenyl]-2,6-di(trichloromethyl)-s-triazine, 4-[o-bromo-p-N,N-di(chloroethyl)aminophenyl]-2,6-di(trichloromethyl)-s-triazine, 4-[o-chloro-p-N,N-di(chloroethyl)aminophenyl]-2,6-di(trichloromethyl)-s-triazine, 4-[o-fluoro-p-N,N-di(chloroethyl)aminophenyl]-2,6-di(trichloromethyl)-s-triazine, 4-[m-bromo-p-N,N-di(chloroethyl)aminophenyl]-2,6-di(trichloromethyl)-s-triazine, 4-[m-chloro-p-N,N-di(chloroethyl)aminophenyl]-2,6-di(trichloromethyl)-s-triazine,

4-[m-fluoro-p-N,N-di(chloroethyl)aminophenyl]-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbnylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, and 4-(o-fluoro-p-N-chloroethylaminophenyl)-2,6-di(trichloromethyl)-s-triazine.

Examples of the photopolymerization initiator further include: TAZ series manufactured by Midori Chemical Co. (for example TAZ-107, TAZ-110, TAZ-104, TAZ-109, TAZ-140, TAZ-204, TAZ-113 and TAZ-123: all trade names);

T-series manufactured by PANCHIM Co. (for example T-OMS, T-BMP, T-R and T-B: all trade names);

IRGACURE® series manufactured by Ciba Specialty Chemicals, Inc. (for example, IRGACURE® 651, IRGACURE® 184, IRGACURE® 500, IRGACURE® 1000, IRGACURE® 149, IRGACURE® 819, and IRGACURE® 261);

DAROCUR® series manufactured by Ciba Specialty Chemicals, Inc. (for example, DAROCUR® 1173);

4,4′-bis(diethylamino)-benzophenone, 2-(O-benzoyloxime)-1-[4-(phenylthio)phenyl]-1,2-octanedione, 2-benzyl-2-dimethylamino-4-morpholinobutylophenone, 2,2-dimethoxy-2-phenylacetophenone, 2-(o-chlorphenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenylimidazolyl dimer and benzoin isopropylether.

Sensitizers and photostabilizers may be used together with any one of the photopolymerization initiator. Specific examples thereof include benzoin, benzoin methylether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, 2-ethoxyxanthone, thioxanthone, 2,4-diethyl thioxanthone, acridone, 10-butyl-2-chloro acridone, benzyl, dibenzalacetone, p-(dimethylamino)phenylstyryl ketone, p-(dimethylamino)phenyl-p-methylstyryl ketone, benzophenone, p-(dimethylamino)benzophenone (or Michler's ketone), p-(diethylamino)benzophenone and benzoanthrone, benzothiazole compounds described in JP-B No. 51-48516, and TINYVIN 1130 and 400 (both trade names, manufactured by Ciba Specialty Chemicals, Inc.).

(D) Pigment

In the photo-curable composition of the invention, one or more among various inorganic pigments or organic pigments, which are conventionally known, can be used by mixing therein.

Considering that high light transmittance is desired to the photo-curable composition, the pigment (D) used in the invention is preferably in a fine granular form regardless of whether it is an inorganic pigment or an organic pigment. Further, taking handling properties into consideration, an average particle diameter of the pigment is preferably 0.01 μm to 0.1 μm, and more preferably 0.01 μm to 0.05 μm. Examples of the inorganic pigment include metal compounds such as metal oxides or metal complex salts. Specific examples thereof include metal oxides such as iron, cobalt, aluminum, cadmium, lead, copper, titanium, magnesium, chromium, zinc, antimony, and composite oxides of any of the metals.

Examples of the organic pigment include C.I. Pigment Yellow 11, 24, 31, 53, 83, 93, 99, 108, 109, 110, 138, 139, 147, 150, 151, 154, 155, 167, 180, 185, and 199;

C.I. Pigment Orange 36, 38, 43, and 71;

C.I. Pigment Red 81, 105, 122, 149, 150, 155, 171, 175, 176, 177, 209, 220, 224, 242, 254, 255, 264, and 270;

C.I. Pigment Violet 19, 23, 32, and 39;

C.I. Pigment Blue 1, 2, 15, 15:1, 15:3, 15:6, 16, 22, 60, and 66;

C.I. Pigment Green 7, 36, and 37;

C.I. Pigment Brown 25 and 28;

C.I. Pigment Black 1 and 7; and

carbon black.

Preferable examples of the pigment to be used in the invention include the followings, but are not limited thereto.

C.I. Pigment Yellow 11, 24, 108, 109, 110, 138, 139, 150, 151, 154, 167, 180, and 185;

C.I. Pigment Orange 36 and 71;

C.I. Pigment Red 122, 150, 171, 175, 177, 209, 224, 242, 254, 255, and 264;

C.I. Pigment Violet 19, 23, and 32;

C.I. Pigment Blue 15:1, 15:3, 15:6, 16, 22, 60, and 66; and

C.I. Pigment Black 1

Each of these organic pigments can be used singly. Alternatively, any of these organic pigments can be used in various combinations thereof in order to improve the color purity. Specific examples of the organic pigment and combinations thereof are shown below.

Examples of the pigments to be used for a red pattern in the invention include: (i) a pigment selected from the group consisting of an anthraquinone pigment, a perylene pigment, and a diketopyrrolopyrrole pigment; (ii) a pigment containing plural pigments, among which at least one is selected from the of the pigment (i); and (iii) a mixture of the red pigment (i) or (ii) with a yellow pigment that includes one pigment selected from the group consisting of a disazo yellow pigment, an isoindolin yellow pigment, and a quinophthalone yellow pigment; and (iv) a mixture of the red pigment (i) or (ii) with a yellow pigment containing plural pigments, among which at least one is selected from the group consisting of a disazo yellow pigment, an isoindolin yellow pigment, and a quinophthalone yellow pigment. Examples of the anthraquinone pigment include C.I. Pigment Red 177. Examples of the perylene pigment include C.I. Pigment Red 155 and C.I. Pigment Red 224. Examples of the diketopyrrolopyrrole pigment include C.I. Pigment Red 254. From the point of view of color reproductivity, the red pigment is preferably used by mixing with C.I. Pigment Yellow 139. From the viewpoint of reducing the light transmittance and improving the color purity, the content ratio (mass ratio) of the Red Pigment to the Yellow Pigment in a mixture of the organic pigment is preferably from 100:5 to 100:75. More preferably, the content ratio (mass ratio) is from 100:10 to 100:50.

As a pigment for green pattern, a phthalocyanine halide pigment may be used singly. Alternatively, a mixture of a green pigment and a disazo yellow pigment, a quinophthalone yellow pigment, an azomethine yellow pigment or an isoindolin yellow pigment may be used. Preferable examples of such a mixture include mixtures of one of C.I. Pigment Green 7, 36, and 37 and one of C.I. Pigment Yellow 83, C.I. Pigment Yellow 138, C.I. Pigment Yellow 139, C.I. Pigment Yellow 150, C.I. Pigment Yellow 180, and C.I. Pigment Yellow 185. The content ratio (mass ratio) of the green pigment to the yellow pigment in a pigment for green pattern is preferably 100:5 to 100:150.

As a pigment for blue pattern, a phthalocyanine pigment may be used singly. Alternatively, a mixture of the blue pigment and a dioxazine violet pigment may be used. Preferable examples of such a mixture include a mixture of C.I. Pigment Blue 15:6 and C.I. Pigment Violet 23. The content ratio (mass ratio) of the Blue Pigment to the Violet pigment is preferably 100:0 to 100:30.

Further, a photo-curable composition excellent in dispersibility and dispersion stability can be obtained by using a powdery processed pigment prepared by finely dispersing the above-mentioned pigment into an acrylic resin, a maleic acid resin, a vinyl chloride-vinyl acetate copolymer resin, an ethyl cellulose resin or the like.

As a pigment for black matrices, carbon, titanium oxide, iron oxide, and the like can be used singly or in combination of two or more of them. It is preferable to use a mixture of carbon and titanium oxide. The content ratio (mass ratio) of carbon to titanium oxide in the carbon-titanium oxide mixture is preferably in the range of 100:5 to 100:40. The light transmittance at long wavelengths is reduced and dispersion stability can be excellent by setting the content ratio to be within the range.

The content of the pigment in the photo-curable composition of the invention is preferably 20 to 70% by mass, and more preferably 30 to 60% by mass, relative to the total mass of the composition.

If the content is within the range, the pattern can be further thinned and refined without impairing the effect of the invention.

Pigment Dispersant and Surface Active Agent

Conventionally-known pigment dispersants and surface active agents may be added to the photo-curable composition of the invention in order to improve dispersibility of the pigment. A wide variety of compounds may be used as the dispersing agent. Examples thereof include phthalocyanine compounds such as EFKA-745 (all trade names, manufactured by EFKA Chemicals B.V.) or SOLSPERSE® 5000 (manufactured by Zeneka); cationic surface active agents such as an organosiloxane polymer KP341 (trade name, manufactured by Shin-Etsu Chemical Co., Ltd.), (meth)acrylic acid(co)polymer POLYFLOW Nos. 75, 90, and 95 (all trade names, manufactured by Kyoeisha Chemical Co., Ltd.), and W001 (trade name, manufactured by Yusho); nonionic surface active agents such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester; anionic surface active agents such as W004, W005, and W017 (all trade names, manufactured by Yusho); polymer dispersing agents such as EFKA-46, EFKA-47, EFKA-47EA, EFKA polymer 100, EFKA polymer 400, EFKA polymer 401, EFKA polymer 450 (all trade names, manufactured by Morishita Sangyo), DISPERSE AID 6, DISPERSE AID 8, DISPERSE AID 15, and DISPERSE AID 9100 (all trade names, manufactured by SAN NOPCO LIMITED); various types of SOLSPERSE® dispersing agents such as SOLSPERSE® 3000, 5000, 9000, 12000, 13240, 13940, 17000, 24000, 26000, and 28000 (manufactured by Zeneka); ADEKA PLURONIC L31, F38, L42, L44, L61, L64, F68, L72, P95, F77, P84, F87, P94, L101, P103, F108, L121, P-123 (all trade names, manufactured by Asahi Denka Kogyo Co., Ltd.); and ISONET S-20 (trade name, manufactured by Sanyo Chemical Industries Co., Ltd.).

A thermal polymerization inhibitor is preferably added to the photo-curable composition of the invention. Useful examples of the thermal polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol) and 2-mercptobenzoimidazole.

Cross-Linking Agent

The photo-curable composition of the invention may form a film that has been more highly cured by additionally using a cross-linking agent. The cross-linking agent is not particularly restricted so long as it is able to cure the film by a cross-linking reaction. Examples of the cross-linking agent include (a) an epoxy resin, (b) a melamine compound, a guanamine compound, a glycoluril compound or a urea compound, substituted with at least one substituent selected from a methylol group, an alkoxymethyl group and an acyloxymethyl group, and (c) a phenol compound, a naphthol compound or a hydroxyanthracene compound, substituted with at least one substituent selected from a methylol group, an alkoxymethyl group and an acyloxymethyl group. A polyfunctional epoxy resin is preferable among them.

The epoxy resin (a) may be any one of epoxy resins having an epoxy group and cross linking property. Examples of the epoxy resin include divalent glycidyl group-containing low molecular weight compounds such as bisphenol A diglycidyl ether, ethyleneglycol diglycidyl ether, butanediol diglycidyl ether, hexanediol diglycidyl ether, dihydroxybiphenyl diglycidyl ether, phthalic acid diglycidyl ester or N,N-diglycidyl aniline; trivalent glycidyl group-containing low molecular weight compounds such as trimethylolpropane triglycidyl ether, trimethylolphenol triglycidyl ether or Tris P-PA triglycidyl ether; tetravalent glycidyl group-containing low molecular weight compounds such as pentaerythritol tetraglycidyl ether or tetramethylol bisphenol A tetraglycidyl ether; polyvalent glycidyl group-containing low molecular weight compounds such as dipentaerythritol pentaglycidiy ether or dipentaerythritol hexaglycidiyl ether; and glycidyl group-containing polymer compounds such as polyglycidyl (meth)acrylate or 1,2-epoxy-4-(2-oxylanyl)cyclohexane adduct of 2,2-bis(hydroxymethyl)-1-butanol.

While the number of substitution of the methylol group, the alkoxymethyl group and the acyloxymethyl group contained in the cross-linking agent (b) is from 2 to 6 in the melamine compound, and is from 2 to 4 in the glycoluril compound, guanamine compound and urea compound, the number is preferably from 5 to 6 in the melamine compound, and is from 3 to 4 in the glycoluril compound, guanamine compound and urea compound.

The melamine compound, the guanamine compound, the glycoluril compound and the urea compound are hereinafter generally named as a compound of (b) (such as “a methylol group-containing compound of (b)”, “an alkoxymethyl group-containing compound of (b)” or “an acyloxymethyl group-containing compound of (b)”).

The methylol group-containing compound of (b) is obtained by heating the alkoxymethyl group-containing compound of (b) in the presence of an acid catalyst such as hydrochloric acid, sulfuric acid, nitric acid or methanesulfonic acid in alcohol. The acyloxymethyl group-containing compound of (b) is obtained by mixing the methylol group-containing compound of (b) with acyl chloride with stirring in the presence of a basic catalyst.

Specific examples of the compound of (b) having the substituent will be described below.

Examples of the melamine compound include hexamethylol melamine, hexamethoxymethyl melamine, a compound obtained by methoxymethylating 1 to 5 methylol groups of hexamethylol melamine, a mixture thereof, hexamethoxyethyl melamine, hexaacyloxymethyl melamine, a compound obtained by acyloxymethylating 1 to 5 methylol groups of hexamethylol melamine and a mixture thereof.

Examples of the guanamine compound include tetramethylol guanamine, tetramethoxymethyl guanamine, a compound obtained by methoxymethylating 1 to 3 methylol groups of tetramethylol guanamine, a mixture thereof, tetramethoxyethyl guanamine, tetraacyloxymethyl gyanamine, a compound obtained by acyloxymethylating 1 to 3 methylol groups of tetramethylol guanamine, and a mixture thereof.

Examples of the glycoluril compound include tetramethylol glycoluril, tetramethoxymethyl glycoluril, a compounds obtained by methoxymethylating 1 to 3 methylol groups of tetramethylol glycoluril, a mixture thereof, a compound obtained by acyloxymethylating 1 to 3 methylol groups of tetramethylol glycoluril, and a mixture thereof.

Examples of the urea compound include tetramethylol urea, tetramethoxymethyl urea, a compound obtained by methoxymethylating 1 to 3 methylol groups of tetramethylol urea, a mixture thereof, and tetramethoxyethyl urea.

The compounds of (b) may be used alone or as a combination of any thereof.

The cross-linking compound (c), namely, the phenol compound, the naphthol compound or the hydroxyanthracene compound, substituted with at least one group selected from a methylol group, an alkoxymethyl group and an acyloxymethyl group, not only suppresses intermixing of an overcoat photoresist by thermal cross-linking as is similar to the cross-linking agent (b) does, but also enhances the strength of the film formed thereby. These compounds are hereinafter generally named as a compound of (c) (methylol group-containing compound, alkoxymethyl group-containing compound or acyloxymethyl group-containing compound).

The number of the methylol group, the acyloxymethyl group or the alkoxymethyl group contained in the cross-linking agent (c) is required to be at least 2 per one molecule.

The compound of (c) is preferably the compound in which all the positions 2 and 4 of a phenol compound, which is a skeleton thereof, are substituted. The compound of (c) is also preferably the compound in which all of the ortho- and para-positions relative to a OH group of a naphthol compound or a hydroxyanthracene compound, which is a skeleton thereof, are substituted. The position 3 or 5 of the phenol compound may be substituted or non-substituted.

The positions other than the ortho-position relative to the —OH group in the naphthol compound may be substituted or non-substituted.

The methylol group-containing compound of (c) is obtained by using a compound, in which the ortho-position or para-position relative to the phenolic —OH group (namely, second position of fourth position) is substituted with hydrogen, as a starting material, and by allowing the compound to react with formalin in the presence of a basic catalyst such as sodium hydroxide, potassium hydroxide, ammonia or tetraalkyl ammonium hydroxide.

The alkoxymethyl group-containing compound of (c) is obtained by heating the methylol group-containing compound of (c) in the presence of an acid catalyst such as hydrochloric acid, sulfuric acid, nitric acid or methanesulfonic acid in alcohol.

The acyloxymethyl group-containing compound of (c) is obtained by allowing the methylol group-containing compound of (c) to react with acyl chloride in the presence of a basic catalyst.

Examples of the skeleton compound in the cross-linking agent (c) include phenol compounds, naphthol compounds and hydroxyanthracene compounds, in each of which an ortho- or para-position relative to a phenolic —OH group therein is non-substituted. Examples of the compound available include phenol, isomers of cresol, 2,3-xylenol, 2,5-xylenol, 3,4-xylenol, 3,5-xylenol, bisphenols such as bisphenol A, 4,4′-bishydroxybiphenyl, TRIS P-PA (trade name, manufactured by Honshu Chemical Co.), naphthol, dihydroxynaphthalene and 2,7-dihydroxyanthracene.

Specific examples of the phenol compounds or the naphthol compounds of the cross-linking agent (c) include compounds in which one or two methylol groups of trimethylol phenol, tri(methoxymethyl)phenol and trimethylol phenol are methoxymethylated; compounds in which one or two methylol groups in trimethylol-3-cresol, tri(methoxymethyl)-3-cresol or trimethylol-3-cresol are methoxymethylated; compounds in which one to three methylol groups of dimethylol cresol such as 2,6-dimethylol-4-cresol, tetramethylol bisphenol A, tetramethoxymethyl bisphenol A or tetramethylol bisphenol A are methoxymethylated; hexamethylol compounds of tetramethylol-4,4′-bishydroxybiphenyl, tetramethoxymethyl-4,4′-bishydroxybiphenyl and a hexamethylol compound of TRIS P-PA (described above); a hexamethoxymethyl compound of TRIS P-PA (described above); compounds in which one to five methylol groups of the hexamethylol compound of TRIS P-PA (described above) are methoxymethylated; and bishydroxymethyl naphthalenediol.

Examples of the hydroxyanthracene compound include 1,6-dihydroxymethyl-2,7-dihydroxyanthracene.

Examples of the acyloxymethyl group-containing compound include compounds in which a part or all of the methylol groups of the methylol group-containing compound are acyloxymethylated.

Trimethylolphenol, bishydroxymethyl-p-cresol, tetramethylol bisphenol A, a hexamethylol compound of TRIS P-PA (described above), compounds in which all methylol groups of each of these phenol compounds are substituted with alkoxymethyl groups, and compounds in which one or more methylol groups of each of these are substituted with alkoxymethyl groups are preferable among these compounds.

The compound of (c) may be used alone or as a combination of any thereof.

Solvents and Other Components

A solvent to be used in the invention is not particularly limited as long as it can satisfy the dispersibility and coating of photo-curable composition. It is preferable to select a solvent considering particularly the solubility, coating, and safety of pigments and binders.

Preferable examples of the solvent which can be used to form the photo-curable composition of the invention include esters such as ethyl acetate, n-butyl acetate, isobutyl acetate, amyl formate, isoamyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate or ethyl ethoxyacetate;

3-oxypropionic acid alkyl esters such as methyl 3-oxypropionate or ethyl 3-oxypropionate (for example, methyl 3-methoxypropionate, ethyl 3-methoxypropionate, methyl 3-ethoxypropionate and ethyl 3-ethoxypropionate); 2-oxypropionic acid alkyl esters such as methyl 2-oxypropionate, ethyl 2-oxypropionate and propyl 2-oxypropionate (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methyl propionate and ethyl 2-ethoxy-2-methylpropionate);

ethers such as diethyleneglycol dimethyl ether, tetrahydrofuran, ethyleneglycol monomethyl ether, ethyleneglycol monoethyl ether, methyl cellosolve acetate, ethyl cellosolve acetate, ethyl carbitol acetate, butyl carbitol acetate, diethyleneglycol monomethyl ether, diethyleneglycol monoethyl ether, diethyleneglycol monobutyl ether, propyleneglycol methyl ether, propyleneglycol methyl ether acetate, propyleneglycol monoethyl ether acetate or propyleneglycol propyl monoether acetate;

ketones such as methylethyl ketone, cyclohexanone, cyclopentanone, 2-heptanone or 3-heptanone; and aromatic hydrocarbons such as toluene or xylene.

More preferable examples among these include methyl 3-ethoxypropionate, ethyl 3-ethoxypropionate, ethyl cellosolve acetate, ethyl lactate, diethyleneglycol dimethyl ether, butyl acetate, methyl 3-methoxypropionate, 2-heptanone, cyclohexanone, ethyl carbitol acetate, butyl carbitol acetate, propyleneglycol monomethyl ether and propyleneglycol monomethyl ether acetate. Most preferable examples among these include methyl 3-ethoxypropionate, cyclohexanone, and propyleneglycol monomethyl acetate.

Any of additives such as a filler, polymer compounds other than those described above, a surfactant, an adhesion accelerating agent, an antioxidant, ultraviolet absorber or a coagulation inhibitor may be additionally used in the photo-curable composition of the invention if desired.

Specific examples of the additives include: fillers such as glass or alumina; polymer compounds other than binder resins such as polyvinyl alcohol, polyacrylic acid, polyethyleneglycol monoalkyl ether, or polyfluoroalkyl acrylate; surfactants such as a nonionic surfactant, a cationic surfactant, or an anionic surfactant; adhesion accelerating agents such as vinyltrimethoxy silane, vinyltriethoxy silane, vinyltris(2-methoxyethoxy)silane, N-(2-aminoethyl)-3-aminopropyl methyldimethoxysilane, N-(2-aminoethyl)-3-aminopropyl trimethoxysilane, 3-aminopropyl triethoxysilane, 3-glycidoxypropyl trimethoxysilane, 3-glycidoxypropylmethyl dimethoxysilane, 2-(3,4-epoxycyclohexyl)ethyl trimethoxysilane, 3-chloropropylmethyl dimethoxysilane, 3-chloropropyl trimethoxysilane, 3-methacryloxypropyl trimethoxysilane or 3-mercaptopropyl trimethoxysilane; antioxidants such as 2,2-thiobis(4-methyl-6-t-butylphenol) or 2,6-di-t-butylphenol; UV absorbing agents such as 2-(3-t-butyl-5-methyl-2-hydroxyphenyl)-5-chlorobenzotriazole or alkoxy benzophenone; and coagulation inhibitors such as sodium polyacrylate.

An organic carboxylic acid, which is preferably a low molecular weight organic carboxylic acid having a molecular weight of 1,000 or less, may be added to the photo-curable composition of the invention for further improving development property by enhancing solubility of non-irradiated portions to an alkali solution.

Specific examples of the organic carboxylic acid include aliphatic monocarboxylic acids such as a formic acid, an acetic acid, a propionic acid, a butyric acid, a valeric acid, a pivalic acid, a capronic acid, a diethylacetic acid, an enanthic acid or a caprylic acid; aliphatic dicarboxylic acid such as an oxalic acid, a malonic acid, a succinic acid, a glutaric acid, an adipic acid, a pimelic acid, a suberic acid, an azelaic acid, a cebacic acid, a brassylic acid, a methylmalonic acid, an ethylmalonic acid, a dimethylmalonic acid, a methylsuccinic acid, tetramethylsuccinic acid or a citraconic acid; aliphatic tricarboxylic acid such as a tricarbarylic acid, an aconitic acid or a camphoronic acid; aromatic monocarboxylic acid such as a benzoic acid, a toluic acid, a cuminic acid, a hemellitic acid or a mesitylenic acid; aromatic polycarboxylic acid such as a phthalic acid, an isophthalic acid, a terephthalic acid, a trimellitic acid, a trimesic acid, a mellophanic acid or a pyromellitic acid; and other carboxylic acid such as a phenylacetic acid, a hydratropic acid, a hydrocinnamic acid, a mandelic acid, a phenylsuccinic acid, an atropic acid, a cinnamic acid, a methyl cinnamate, benzyl cinnamate, a cinnamylidene acetic acid, a coumaric acid or an unberic acid.

Preferable Combination and Content of Each Component in Photo-Curable Composition

With respect to a photo-curable composition of the invention, adjustment of the combinations of each component and the content ratios enables formation of a yet further refined pattern, an excellent pattern shape to be obtained, and further suppression of generation of development residue.

From this viewpoint, preferable examples of the mass content of each component to total solid content of the photo-curable composition include: combinations of (B) 2 to 50% by mass of the particular photo-curable compound, (C) 1.0 to 30% by mass of oxime photopolymerization initiator, and (D) 20 to 70% by mass of pigment, and more preferable examples thereof include: combinations of (B) 2 to 30% by mass of the particular photo-curable compound, (C) 2 to 25% by mass of oxime photopolymerization initiator, and (D) 30 to 60% by mass of pigment.

From the same viewpoint as described above, preferable examples of the combinations of (D) the content of a pigment, (B) the kind of particular photo-curable compound and (C) type of oxime photopolymerization initiator include combinations in which (D) the mass content of the pigment to total solid content of the photo-curable composition is 20 to 70% by mass, (B) the particular photo-curable compound is selected from the group consisting of the exemplified compounds (3), (4), (5), (7), (9), (a), (b), (e), and (f), and (C) the oxime photopolymerization initiator is CGI-124 or CGI-242 (both trade names described above). Further, particularly preferable examples thereof include combinations in which (D) the mass content of the pigment to total solid content of the photo-curable composition is 30 to 60% by mass, (B) the particular photo-curable compound is selected from the group consisting of the exemplified compounds (3), (4), (5), (a), (b), and (e), and (C) the oxime photopolymerization initiator is CGI-124 or CGI-242 (both trade names described above).

The photo-curable composition of the invention can be used to form a pattern of a color filter for a liquid crystal display element, or a color filter for a solid state imager (e.g. CCD, etc.). The photo-curable composition of the invention is particularly effective in forming a refined pattern.

Specifically, the photo-curable composition of the invention is effective in forming a pattern with a dimension of 2.5 μm or less and is particularly effective in forming a pattern with a dimension of 2.0 μm or less.

Further, the photo-curable composition of the invention is effective in forming a pattern with a film thickness of 1.5 μm or less and is particularly effective in forming a pattern with a film thickness of 1.0 μm or less.

Color Filter and Method of Producing Thereof

A color filter of the invention is produced by using the photo-curable composition. The method for producing a color filter of the invention is not particularly limited. Preferable examples of the method include a method including: forming a coating film by applying the photo-curable composition onto a substrate directly or via other layers, which may further be followed by drying as needed; exposing the coating film through a mask to form a specific pattern; and developing by processing the exposed coating film with an alkaline developer, which may further be followed by heat-treating the processed coating film (post-baking) as needed. The colored pattern can be formed by using these processes.

Further, the production method of the color filter of the invention may include curing the colored pattern by heating and exposure, if necessary.

The process of forming the coating film may involve a process in which a photo-curable composition is applied onto a substrate by a coating method such as spin coating, flow-casting coating, roll coating, slit coating or the like and, if necessary, the thus applied composition is dried to form the coating film.

Examples of the substrate include silicon substrates and solid state imagers such as CCD or CMOS. In some cases, a black matrix isolating each pixel may be formed on these substrates.

In order to improve adherence between the substrate and an upper layer, prevent diffusion of substances, or planarize the surface of the substrate, an undercoat layer may be provided on the substrate, if necessary.

In the exposure process, a specific pattern is exposed to the coating film formed by forming the coating film through a mask. Examples of the radiation used in exposure include ultraviolet radiation, and particularly preferably used examples thereof include g-rays, h-rays, and i-rays. Among these, i-rays are particularly preferable from the viewpoint of forming a finer pattern.

The developing includes performing a development treatment of the exposed coating film by an alkaline developer or the like. Any alkaline developer may be used so long as the developer dissolves non-exposed (non-irradiated) portions of the photo-curable composition of the invention while the exposed (irradiated) portion is insoluble thereto. Specific examples of the developer include a combination of various organic solvents and an aqueous alkali solution.

Examples of the organic solvents include those described as the organic solvents used for preparing the photo-curable composition of the invention.

The aqueous alkali solution may be prepared by dissolving an alkaline compound such as sodium hydroxide, potassium hydroxide, sodium carbonate, sodium silicate, sodium metasilicate, aqueous ammonia, ethylamine, diethylamine, dimethyl ethanolamine, tetramethyl ammonium hydroxide, tetraethyl ammonium hydroxide, choline, pyrrole, piperidine or 1,8-diazabicyclo-[5.4.0]-7-undecene to a water-based liquid so as to be in a concentration from 0.001 to 10% by mass, preferably from 0.01 to 1% by mass. Washing a thus-developed coating layer with water after development is generally further performed in a case where such a developer consisting of the aqueous alkali solution is used.

The alkali concentration of an alkaline aqueous solution used in the alkaline developer to be used in the invention is preferably adjusted to be in a range of pH 1 to 13 and more preferably in a range of pH 11.5 to 12.5. If the alkali concentration is within the range described above, abrasion or roughness of pattern edge and surface can be more effectively suppressed and the ratio of residual coating film on the substrate after the development can be further improved. Additionally, reductions in speed of development and generation of development residue can be more effectively suppressed.

In the developing process, it is preferable to perform development with a developer consisting of such an alkaline aqueous solution. Examples of the developing method include a dip method, a spray method, a paddle method, and the temperature for operating the developing is preferably from 15 to 40° C. Generally, it is preferable to rinse a thus-developed pattern under running water.

In the production method of the color filter of the invention, it is preferable that heat-treatment is carried out during the post-baking in order to completely cure the coating film after the development. The heating temperature in the heating is preferably 100 to 300° C., and more preferably 150 to 250° C. Additionally, the heating time is preferably for about 2 minutes to 1 hour, and more preferably for about 3 minutes to 30 minutes.

While the color filter of the invention may be used for a liquid crystal display device (LCD), it is preferably used for a CCD element, a CMOS element or the like having a high resolution such as those having a pixel number exceeding 106 pixels. The color filter of the invention may be used, for example, as a color filter disposed between light-receiving portions of the pixels constituting CCD and a micro-lens for focusing.

Among these, the color filter of the invention is used preferably as a color filter with a pattern dimension of 2.5 μm or less (more preferably 2.0 μm or less), and most preferably as a color filter with a pattern dimension of 2.5 μm or less (more preferably 2.0 μm or less) and a film thickness of 1.5 μm or less (more preferably 1.0 μm or less).

### EXAMPLES

While the present invention is described in detail below with reference to examples, the scope of the invention is not restricted to the examples as long as it does not exceed the primary configuration of the invention. “Parts” in the following examples denote “parts by mass” unless otherwise defined.

### Example 1

### 1) Preparation of Undercoat Liquid

An undercoat liquid was prepared by mixing and dissolving the following compositions.

| | | |
|---|---|---|
| propyleneglycol monomethylether acetate (PGMEA) | 19.20 | parts |
| Ethyl lactate | 36.67 | parts |
| Binder [benzyl methacrylate/methacrylic | 30.51 | parts |
| acid/methacrylic acid-2-hydroxyethyl | | |
| copolymer: 41% PGMEA solution with a molar ratio = | | |
| 60/20/20] | | |
| Dipentaerythritol hexaacrylate | 12.20 | parts |
| (photopolymerizable compound) | | |
| Polymerization inhibitor (p-methoxyphenol) | 0.0061 | parts |
| Fluorinated surfactant (trade name: F-475, | 0.83 | parts |
| manufactured by Dainippon Ink & Chemicals Inc.) | | |
| Photopolymerization initiator (trihalomethyl | 0.586 | parts |
| triazine Photopolymerization initiator, trade | | |
| name: TAZ-107, manufactured by Midori Chemical Co.) | | |

### 2) Production of Silicon Wafer Substrate with Undercoat Layer

The undercoat liquid was uniformly coated onto a silicon wafer (size: 6×6 inches) by a spin coater, and the thus-formed layer was heated at 120° C. for 120 seconds or more on a hot plate. The rotation number of the spin coater for the coating was adjusted so that a thickness of the coated layer after dried becomes about 2 μm.

The thus heated coated layer was further subjected to heating in an oven at 220° C. for 1 hour so as to be cured to provide an undercoat layer.

A 6×6 inches silicon wafer substrate having thereon an undercoat layer was thus formed.

### 3) Preparation of Photo-Curable Composition A-1

The following components were mixed with a stirrer to prepare a color resist liquid (photo-curable composition A-1) with a solid content of 13% by mass.

| | | |
|---|---|---|
| Benzyl methacrylate/methacrylic acid copolymer | 1.83 | parts |
| (molar ratio = 70/30) (binder polymer) | | |
| Mixtures of exemplified compound (4) and | 1.41 | parts |
| dipentaerythritol hexa acrylate (hereinafter | | |
| referred to as DPHA) in a 1:1 ratio (photo-curable | | |
| compound) | | |
| Oxime photopolymerization initiator (trade name: | 0.5 | part |
| CGI-124, manufactured by Ciba Specialty Chemicals) | | |
| Pigment dispersion solution with pigment (Pigment | 61.6 | parts |
| Blue 15:6) (solid contents: 15%, pigment contents | | |
| in the solid contents: 60%) | | |
| Propylene-glycol-monomethyl-ether acetate (solvent) | 16.7 | parts |
| 3-ethoxy ethyl propionate (solvent) | 17.9 | parts |

### 4) Production of Color Filter

The thus obtained color resist liquid was uniformly applied onto the undercoat layer of the silicon wafer substrate by spin coating to form a coating film. Then, the coating film was heat-treated on a hot plate having a surface temperature of 100° C. for 120 seconds to form a color resist layer. Here, the spin coating rotation speed was adjusted so that the thickness of the coating film after the heat-treatment became about 1.0 μm.

Next, an i-ray stepper (trade name: FPA-3000i5+, manufactured by Canon Inc.) was used as an exposure device and 25 portions in the color resist layer were subjected to pattern exposure through a photomask while the amount of light exposure was gradually changed in the range of from 1,000 to 25,000 J/m² with an interval of 1,000 J/m².

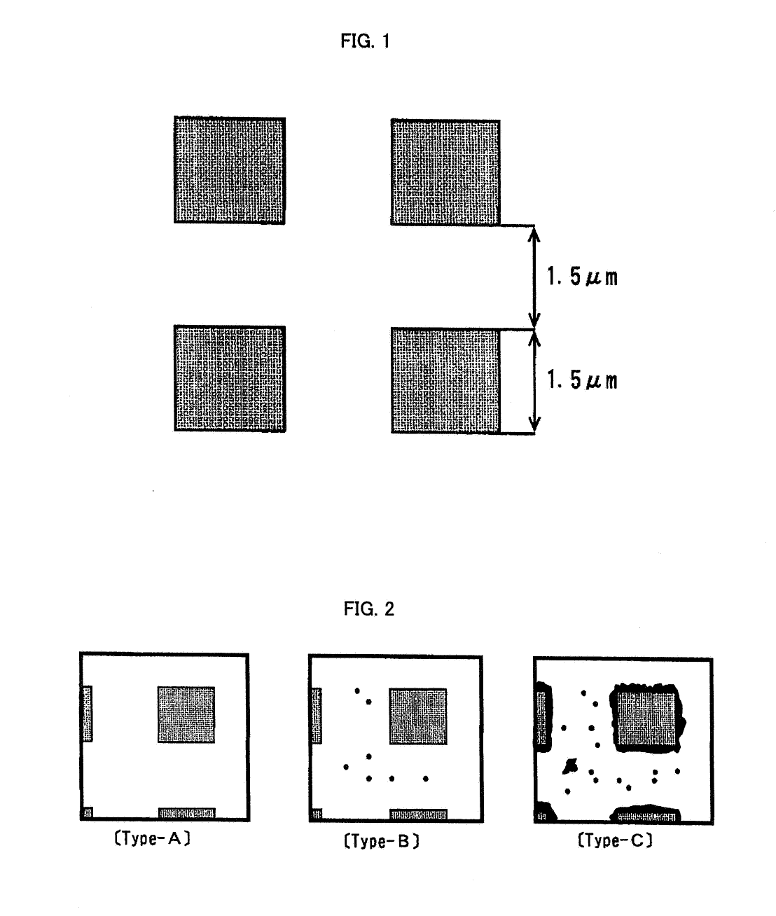

The photomask used herein had a mask pattern having 1.5 μm×1.5 μm square pixels arranged in an area of 3 mm×4 mm as shown in FIG. 1.

After pattern exposure, the resulting color resist layer was subjected to paddle development at room temperature for 60 seconds using an organic alkaline developing solution (40% by mass aqueous solution of a commercially available developer (trade name: CD-2000, manufactured by FUJIFILM Electronic Materials Co., Ltd.)).

After the paddle development, the resultant product was rinsed with pure water by the spin shower method for 20 seconds. Further, the resultant product was washed with pure water for 20 seconds. Then, water drops remaining on the wafer were blown off with high-pressure air and the substrate was subjected to air-drying, followed by heat treatment on a hot plate with a surface temperature of 200° C. for 5 minutes to form a pattern having square pixels.

A color filter having an undercoat layer and a pattern having square pixels in this order on a silicon wafer was thus formed.

### 5) Evaluations

The resulting color filter was evaluated in terms of the “minimum light exposure” and the “development residue”.

Evaluation of Minimum Light Exposure

Each of the patterns having 1.5 μm×1.5 μm square pixels formed by a varying light exposure amount as described above was observed in a reflection mode at a magnification of 1000 times using an optical microscope (trade name: BX60, manufactured by OLYMPUS) and the minimum light exposure determined.

Amounts of light exposure which were insufficient to cure films and generated at least one missing portion in the pattern were rejected. Among amounts of light exposure by which the patterns could be formed without any missing portions, the minimum amount of light exposure required to form the pattern was designated as the “minimum light exposure”.

Evaluation of Development Residue

The peripheral portions of each of the 1.5 μm×1.5 μm square pixels of the pattern formed with an amount of light exposure of 7,000 J/m² were observed and spaces between the square pixels were observed to determine if there were certain adherents or unmelted residual portions (in other words, the level of the generation of development residue) using a side length SEM (trade name: S-9260S, manufactured by Hitachi, Ltd.).

The observed results were classified into the three levels of Type-A, Type-B, and Type-C in residue-decreasing level order (namely, in the order of suppression of the generation of residue). The criteria for classifying the degree of the development residue are shown in the following Table 1, and views showing typical aspects in each of the types are shown in FIG. 2.

TABLE 1

| | Type-A | Type-B | Type-C |
|---|---|---|---|
| Residue in | None | None | Large amount |
| peripheral portions | | | |
| Residue between | None | Small amount | Large amount |
| square pixels | | | |

### Examples 2 to 26 and Comparative Examples 1 to 3

Color filters of Examples 2 to 26 and Comparative Examples 1 to 3 were produced in the same manner as in Example 1 except that a photo-curable compound and a photopolymerization initiator used in the preparation of photo-curable composition A-1 were changed as shown in Tables 2 to 4 so as to prepare photo-curable compositions A-2 to A-26 and photo-curable compositions S-1 to S-3. Further, evaluations of Examples 2 to 26 and Comparative Examples 1 to 3 were carried out in the same manner as for Example 1.

In Tables 2 to 4, the term “DPHA” denotes dipentaerythritol hexaacrylate. In addition, the phrase “exemplified compound (5): DPHA=3:1” indicates that a mixture obtained by mixing exemplified compound (5) with DPHA in a mass ratio 3:1 was used as a photo-curable compound. Other phrases similar to this similarly indicate mixtures having mixing mass ratios described therein.

The results are shown in the following Tables 2 to 4.

TABLE 2

| | | | | Result of determination | |
|---|---|---|---|---|---|
| | | | | Minimum | |
| | | Photo-curable | Photopolymerization | light | Type of |
| | Composition | compound | initiator | exposure | residue |
| Example 1 | A-1 | Exemplified | CGI-124 | 4000 J/m² | Type-A |
| | | compound | | | |
| | | (4):DPHA = 1:1 | | | |
| Example 2 | A-2 | Exemplified | CGI-124 | 4000 J/m² | Type-A |
| | | compound | | | |
| | | (5):DPHA = 3:1 | | | |
| Example 3 | A-3 | Exemplified | CGI-124 | 5000 J/m² | Type-A |
| | | compound | | | |
| | | Exemplified | | | |
| | | compound | | | |
| | | (6):DPHA = 4:1 | | | |
| Example 4 | A-4 | Exemplified | CGI-124 | 6000 J/m² | Type-A |
| | | compound | | | |
| | | (7):DPHA = 7:3 | | | |
| Example 5 | A-5 | Exemplified | CGI-124 | 6000 J/m² | Type-A |
| | | compound | | | |
| | | (3):DPHA = 2:1 | | | |
| Example 6 | A-6 | Exemplified | CGI-124 | 7000 J/m² | Type-A |
| | | compound | | | |
| | | (3):pentaerythritol | | | |
| | | tetracrylate = 2:1 | | | |
| Example 7 | A-7 | Exemplified | CGI-124 | 5000 J/m² | Type-A |
| | | compound | | | |
| | | (7):DPHA = 3:7 | | | |
| Example 8 | A-8 | Exemplified | CGI-242 | 3000 J/m² | Type-A |
| | | compound | | | |
| | | (4):DPHA = 1:1 | | | |
| Example 9 | A-9 | Exemplified | CGI-242 | 5000 J/m² | Type-A |
| | | compound | | | |
| | | (3):pentaerythritol | | | |
| | | tetracrylate = 2:1 | | | |
| Example 10 | A-10 | Exemplified | CGI-124 | 3500 J/m² | Type-A |
| | | compound (4) | | | |
| Example 11 | A-11 | Exemplified | CGI-242 | 3000 J/m² | Type-A |
| | | compound (4) | | | |

TABLE 3

| | | | | Result of determination | |
|---|---|---|---|---|---|
| | | | | Minimum | |
| | | Photo-curable | Photopolymerization | light | Type of |
| | Composition | compound | initiator | exposure | residue |
| Example 12 | A-12 | Exemplified | CGI-124 | 4000 J/m² | Type-A |
| | | compound (5) | | | |
| Example 13 | A-13 | Exemplified | CGI-124 | 5000 J/m² | Type-A |
| | | compound (6) | | | |
| Example 14 | A-14 | Exemplified | CGI-124 | 6000 J/m² | Type-A |
| | | compound (7) | | | |
| Example 15 | A-15 | Exemplified | CGI-242 | 5000 J/m² | Type-A |
| | | compound | | | |
| | | (3):DPHA = 2:1 | | | |
| Example 16 | A-16 | Exemplified | CGI-124 | 4000 J/m² | Type-A |
| | | compound (a) | | | |
| Example 17 | A-17 | Exemplified | CGI-124 | 4500 J/m² | Type-A |
| | | compound (b) | | | |
| Example 18 | A-18 | Exemplified | CGI-124 | 5000 J/m² | Type-A |
| | | compound (c) | | | |
| Example 19 | A-19 | Exemplified | CGI-124 | 7000 J/m² | Type-A |
| | | compound (d) | | | |
| Example 20 | A-20 | Exemplified | CGI-124 | 6000 J/m² | Type-A |
| | | compound (e) | | | |
| Example 21 | A-21 | Exemplified | CGI-124 | 8000 J/m² | Type-A |
| | | compound (f) | | | |
| Example 22 | A-22 | Exemplified | CGI-124 | 5000 J/m² | Type-A |
| | | compound | | | |
| | | (5):Exemplified | | | |
| | | compound | | | |
| | | (b):DPHA = 2:1:3 | | | |
| Example 23 | A-23 | Exemplified | CGI-124 | 8000 J/m² | Type-A |
| | | compound | | | |
| | | (b):DPHA = 1:2 | | | |
| Example 24 | A-24 | Exemplified | CGI-242 | 5000 J/m² | Type-A |
| | | compound (b) | | | |
| Example 25 | A-25 | Exemplified | CGI-242 | 7000 J/m² | Type-A |
| | | compound (e) | | | |
| Example 26 | A-26 | Exemplified | CGI-124 | 3000 J/m² | Type-A |
| | | compound | | | |
| | | (5):Exemplified | | | |
| | | compound (b) = 1:1 | | | |

TABLE 4

| | | | | Result of determination | |
|---|---|---|---|---|---|
| | | | | Minimum | |
| | | Photo-curable | Photopolymerization | light | Type of |
| | Composition | compound | initiator | exposure | residue |
| Comparative | S-1 | Exemplified compound | IRGACURE® 907 | 22000 J/m² | Type-B |
| example 1 | | (4):DPHA = 1:1 | | | |
| Comparative | S-2 | DPHA | CGI-124 | 7000 J/m² | Type-C |
| example 2 | | | | | |
| Comparative | S-3 | Exemplified compound | IRGACURE® 907 | 24000 J/m² | Type-B |
| example 3 | | (b) | | | |

As shown in Tables 2 to 4, when a color filter was produced using a photo-curable composition of the invention (Examples 1 to 26), the minimum light exposure could be reduced and the generation of residue could be suppressed even when a very refined pattern (1.5 μm) was formed.

On the other hand, in Comparative Examples 1 and 3 where IRGACURE® 907 (acetophenone type), which was a photopolymerization initiator other than the oxime type photopolymerization initiator, was used to form the pattern having 1.5 μm×1.5 μm square pixels, the minimum light exposures were increased and larger amounts of development residue were found.

Further, in Comparative Example 2 where a photo-curable compound containing neither an acidic functional group nor an alkyleneoxy chain was used to form a pattern having 1.5 μm×1.5 μm square pixels, a significantly larger amount of development residue was found.

### CROSS-REFERENCE TO RELATED APPLICATION

This application claims priority under 35 USC 119 from Japanese Patent Application Nos. 2006-264606 and 2007-81713, the disclosures of which are incorporated by reference herein.

What is claimed is:

1. A photo-curable composition comprising: (A) a binder polymer; (B) a multifunctional photo-curable compound having at least one selected from the group consisting of acidic functional groups and alkyleneoxy chains; (C) an oxime photopolymerization initiator; and (D) a pigment.

2. The photo-curable composition according to claim 1, wherein the (B) multifunctional photo-curable compound comprises an acidic functional group that is a carboxyl group.

3. The photo-curable composition according to claim 1, wherein the (B) multifunctional photo-curable compound comprises three or more photo-curable functional groups.

4. The photo-curable composition according to claim 1, wherein the (B) multifunctional photo-curable compound comprises at least one selected from the group consisting of a pentaerythritol compound and a dipentaerythritol compound.

5. The photo-curable composition according to claim 1, wherein the (B) multifunctional photo-curable compound comprises at least one selected from the group consisting of a compound represented by Formula (i) or (ii): 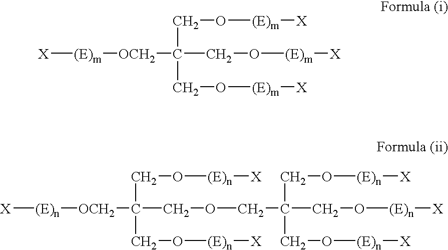
wherein, each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group;
in Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group;
in Formula (ii), the sum of the number of acryloyl groups and the number of methacryloyl groups is 5 or 6; each n independently represents an integer from 0 to 10; and the sum of n is an integer from 0 to 60, provided that if the sum of n is 0, any one X is a carboxyl group.

6. A method for producing a color filter comprising: applying a photo-curable composition onto a substrate; exposing the applied composition through a mask; and developing the exposed composition so as to form a pattern, wherein the photo-curable composition comprises: (A) a binder polymer; (B) a multifunctional photo-curable compound having at least one selected from the group consisting of acidic functional groups and alkyleneoxy chains; (C) an oxime photopolymerization initiator; and (D) a pigment.

7. The method for producing a color filter according to claim 6, wherein the (B) multifunctional photo-curable compound comprises an acidic functional group that is a carboxyl group.

8. The method for producing a color filter according to claim 6, wherein the (B) multifunctional photo-curable compound comprises three or more photo-curable functional groups.

9. The method for producing a color filter according to claim 6, wherein the (B) multifunctional photo-curable compound comprises at least one selected from the group consisting of a pentaerythritol compound and a dipentaerythritol compound.

10. The method for producing a color filter according to claim 6, wherein the (B) multifunctional photo-curable compound comprises at least one selected from the group consisting of a compound represented by Formula (i) or (ii): 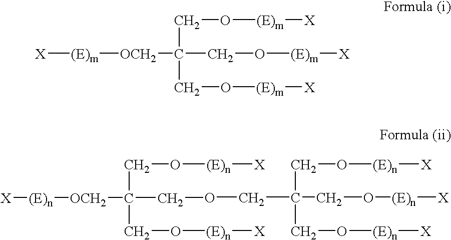
wherein, each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group;
in Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group;
in Formula (ii), the sum of the number of acryloyl groups and the number of methacryloyl groups is 5 or 6; each n independently represents an integer from 0 to 10; and the sum of n is an integer from 0 to 60, provided that if the sum of n is 0, any one X is a carboxyl group.

11. A color filter formed using a photo-curable composition, wherein the photo-curable composition comprises: (A) a binder polymer; (B) a multifunctional photo-curable compound having at least one selected from the group consisting of acidic functional groups and alkyleneoxy chains; (C) an oxime photopolymerization initiator; and (D) a pigment.

12. The color filter according to claim 11, wherein the (B) multifunctional photo-curable compound comprises an acidic functional group that is a carboxyl group.

13. The color filter according to claim 11, wherein the (B) multifunctional photo-curable compound comprises three or more photo-curable functional groups.

14. The color filter according to claim 11, wherein the (B) multifunctional photo-curable compound comprises at least one selected from the group consisting of a pentaerythritol compound and a dipentaerythritol compound.

15. The color filter according to claim 11, wherein the (B) multifunctional photo-curable compound comprises at least one selected from the group consisting of a compound represented by Formula (i) or (ii): 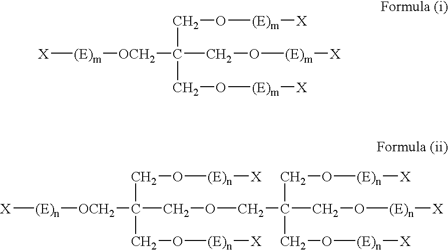
wherein, each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group;
in Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group;
in Formula (ii), the sum of the number of acryloyl groups and the number of methacryloyl groups is 5 or 6; each n independently represents an integer from 0 to 10; and the sum of n is an integer from 0 to 60, provided that if the sum of n is 0, any one X is a carboxyl group.

16. A solid state imager comprising a color filter formed using a photo-curable composition, wherein the photo-curable composition comprises: (A) a binder polymer; (B) a multifunctional photo-curable compound having at least one selected from the group consisting of acidic functional groups and alkyleneoxy chains; (C) an oxime photopolymerization initiator; and (D) a pigment.

17. The solid state imager according to claim 16, wherein the (B) multifunctional photo-curable compound comprises an acidic functional group that is a carboxyl group.

18. The solid state imager according to claim 16, wherein the (B) multifunctional photo-curable compound comprises three or more photo-curable functional groups.

19. The solid state imager according to claim 16, wherein the (B) multifunctional photo-curable compound comprises at least one selected from the group consisting of a pentaerythritol compound and a dipentaerythritol compound.

20. The solid state imager according to claim 16, wherein the (B) multifunctional photo-curable compound comprises at least one selected from the group consisting of a compound represented by Formula (i) or (ii): 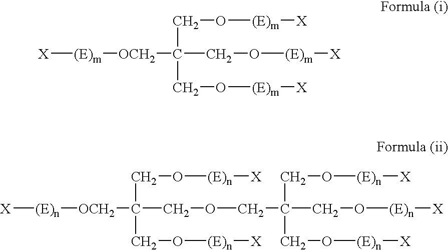
wherein, each of structural units represented by E independently represents —((CH₂)_{y}CH₂O)— or —((CH₂)_{y}CH(CH₃)O)—; each y independently represents an integer from 0 to 10; and each X independently represents an acryloyl group, a methacryloyl group, a hydrogen atom, or a carboxyl group;
in Formula (i), the sum of the number of acryloyl groups and the number of methacryloyl groups is 3 or 4; each m independently represents an integer from 0 to 10; and the sum of m is an integer from 0 to 40, provided that if the sum of m is 0, any one X is a carboxyl group;
in Formula (ii), the sum of the number of acryloyl groups and the number of methacryloyl groups is 5 or 6; each n independently represents an integer from 0 to 10; and
the sum of n is an integer from 0 to 60, provided that if the sum of n is 0, any one X is a carboxyl group.
